(19) United States
(12) Patent Application Publication
(10) Pub. No.: US 2003/0015142 A1
(43) Pub. Date: Jan. 23, 2003

(54) Apparatus for fabricating a semiconductor device

(76) Inventors: Chul Ju Hwang, Kyonggi-do (KR); Kyung Sik Shim, Kyonggi-do (KR)

Correspondence Address: Marger Johnson & McCollom, 1030 SW Morrion Street, Portland, OR, 97205, US

(21) Appl. No.: 09/913,652

(22) PCT Filed: Dec. 15, 2000
(86) PCT No.: PCT/KR00/01466

(30) Foreign Application Priority Data
Dec. 15, 1999 (KR) 1999-57751

(51) Int. Cl. C23C 16/00; C23F 1/00

(52) U.S. Cl. 118/733; 156/345.1

(57) ABSTRACT

An apparatus for fabricating a semiconductor device in which an O-ring can be protected from any thermal damage when used for sealing a reaction chamber or a quartz tube in a high temperature process, the apparatus comprising: a reaction chamber having an upper chamber with an upper flange and a lower chamber with a lower flange, the upper and lower flanges being coupled to define a reaction space sealed from the outer atmosphere; an O-ring inserted between the upper and lower flanges; a heater arranged within the reaction chamber; a water pipe provided within the lower flange; a metal seal provided to the upper surface of the lower flange of the reaction chamber; and a cooling flange provided with a water pipe adapted for cooling water to flow through the water pipe, the cooling flange being coupled with the upper flange of the reaction chamber so that the metal seal can be pressed onto the upper surface of the upper flange of the reaction chamber. With the apparatus, efficiency of cooling water can be maximized by use of a metal seal so that the O-ring close to a high temperature part can be protected from any thermal damage.

### BACKGROUND OF THE INVENTION

1. Field of the Invention

The present invention relates to an apparatus for fabricating a semiconductor device and, more particularly, to an apparatus for fabricating a semiconductor device in which an O-ring can be protected from any thermal damage when used for sealing a reaction chamber or a quartz tube in a high temperature process.

2. Description of the Related Art

In general, a semiconductor device is fabricated in a reaction space which is sealed from outer atmosphere. This kind of reaction space is provided by a reaction chamber or a quartz tube so as to be suitable for a fabrication process. For example, a thermal oxidization or a diffusion process is typically carried out in a quartz tube, and a PVD (physical vapor deposition) or a CVD (chemical vapor deposition) is typically carried out in a reaction chamber.

In order to maintain the reaction chamber or the quartz tube in vacuum, an O-ring is generally used in a sealing for the purpose of closing the inner space from the outer atmosphere. However, essentially the O-ring has bad thermal endurance since it is made of a polymer, and thus may undergo a thermal damage in a high temperature process. Therefore, a leak can take place in the sealing part of the reaction chamber or the quartz tube.

FIG. 1A and FIG. 1B are schematic views for illustrating an apparatus for fabricating a semiconductor device of the prior art, in which FIG. 1A shows an LPCVD (low pressure chemical vapor deposition) apparatus, and FIG. 1B shows a diffuser.

Referring to FIG. 1A, a reaction chamber 10 provides a reaction space closed from the outer atmosphere. The reaction chamber 10 comprises a lower chamber 10a having a lower flange 40a, and an upper chamber 10b having an upper flange 40b. The lower and upper flanges 40a, 40b are coupled to define the reaction chamber 10. The upper reaction chamber 10b is dome shaped and made with quartz. Within the reaction chamber 10, a heater 20 is provided for heating a semiconductor wafer which is settled onto a susceptor (not shown) arranged on the heater 20.

Between the lower and upper flanges 40a, 40b, an O-ring 30 is inserted to prevent any leak from taking place when the inside of the reaction chamber 10 is in vacuum.

Referring to FIG. 1B, a reaction space sealed from the outer atmosphere is provided by a quartz tube 11, and a bulk head 21 is provided around one end of the quartz tube 11 to close the inner space of the quartz tube 11 from the outer atmosphere. An outlet pipe 41 is provided at the bulk head 21 to exhaust gas from the inner space of the quartz tube 11.

Furthermore, O-ring 31 is provided between the bulk head 21 and the quartz tube 11 to prevent any leak from taking place between the same. The O-ring 31 is pressed onto the quartz tube 11 by the bulk head 21.

A heater (not shown) for supplying heat required for a diffusion process may be provided to surround the outer surface of the quartz tube 11, or alternatively provided to supporting means which is located within the quartz tube and supports a wafer settled thereon.

According to the foregoing apparatus for fabricating a semiconductor device of the prior art. a thermal damage may take place to the O-rings 30, 31 which are provided to prevent any leak in the reaction chamber 10 and the quartz tube 11 when carrying out a high temperature vacuum process within the same. And as a result, a leak may take place to the reaction chamber 10 or the quartz tube 11.

Furthermore, since the O-rings 30, 31 are thermally deformed and become tacky, the upper chamber 10b and the quartz tube 11 are frequently broken when separating the lower chamber 10a and the upper chamber 10b or detaching the bulk bead 21 from the quartz tube 1.

### SUMMARY OF THE INVENTION

Therefore, it is an object of the present invention to provide an apparatus for fabricating a semiconductor device wherein the foregoing problems of the prior art can be overcome by enhancing cooling efficiency of an O-ring part.

According to an embodiment of the present invention for obtaining the foregoing object of the present invention, it is provided an apparatus for fabricating a semiconductor device comprising: a reaction chamber having an upper chamber with an upper flange and a lower chamber with a lower flange, the upper and lower flanges being coupled to define a reaction space sealed from the outer atmosphere; an O-ring inserted between the upper and lower flanges; a heater arranged within the reaction chamber; a water pipe provided within the lower flange; a metal seal provided to the upper surface of the lower flange of the reaction chamber; and a cooling flange provided with a water pipe adapted for cooling water to flow through the water pipe, the cooling flange being coupled with the upper flange of the reaction chamber so that the metal seal can be pressed onto the upper surface of the upper flange of the reaction chamber.

According to another embodiment of the present invention for obtaining the foregoing object of the present invention, it is provided an apparatus for fabricating a semiconductor device comprising: a quartz tube for providing a reaction space sealed from the outer atmosphere; a heater for heating the inside of the quartz tube; a bulk head surrounding the quartz tube, and provided with a water pipe in the inside; an O-ring inserted between the bulk head and the quartz tube and pressed onto the quartz tube by the bulk head; and a metal seal inserted between the bulk head and the quartz tube close to the O-ring.

With the apparatus for fabricating a semiconductor device according to the foregoing embodiments of the present invention, efficiency of a cooling water can be maximized by use of a metal seal so that the O-ring close to a high temperature part can be protected from any thermal damage. Therefore, in a reaction chamber or a quartz tube, any leak of gas from a sealed part of the O-ring or any thermal deformation and adhering of the O-ring can be prevented.

### BRIEF DESCRIPTION OF THE DRAWINGS

FIG. 1A and FIG. 1B are schematic views for illustrating an apparatus for fabricating a semiconductor device of the prior art;

FIG. 2 is a schematic view for illustrating an apparatus for fabricating a semiconductor device of the first embodiment of the present invention; and

FIG. 3 is a schematic view for illustrating an apparatus for fabricating a semiconductor device of the second embodiment of the present invention.

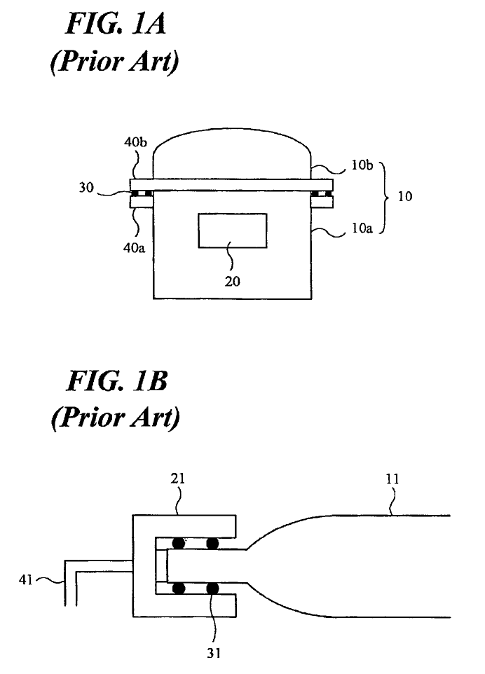

### DESCRIPTION OF THE PREFERRED EMBODIMENT

[Embodiment 1]

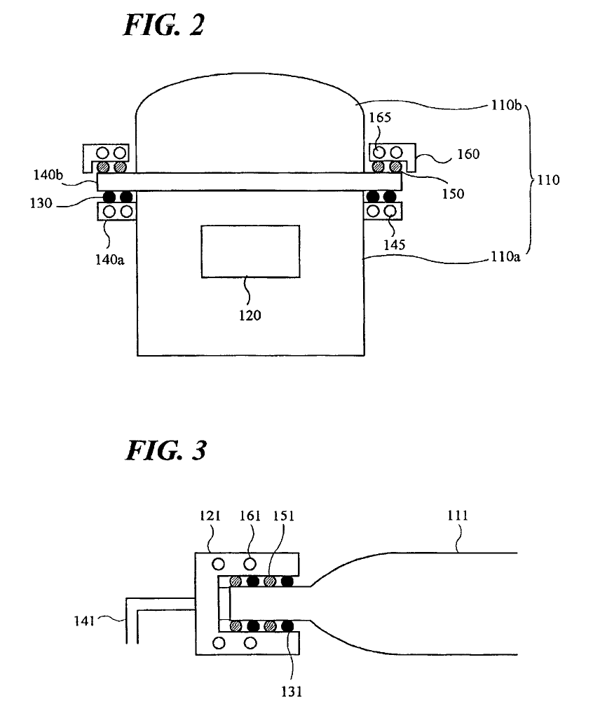

An apparatus for fabricating a semiconductor device according to the first embodiment of the present invention will now be described in reference to the FIG. 2.

Referring to FIG. 2, a reaction chamber 110 is arranged to provide a reaction space closed from the outer atmosphere. Herein, the reaction chamber 110 comprises a lower chamber 110a having a lower flange 140a and an upper chamber 110b having an upper flange 140b. The lower and upper flanges 140a, 140b are coupled to define the reaction chamber 110. The upper chamber 110b is dome shaped and made with quartz. Within the reaction chamber 110, a heater 120 is provided for heating a semiconductor wafer which is settled on a susceptor (not shown) arranged on the heater 120.

Between the lower and upper flanges 140a, 140b, an O-ring 130 is inserted to prevent any leak from taking place when the inside of the reaction chamber 110 is in vacuum. Inside the lower flange 140a of the lower chamber 110a, a first cooling pipe 145 is provided so that cooling water can flow through the same to prevent the O-ring 130 from any thermal damage.

On the other hand, since only the lower part of the O-ring 130 is cooled by the first water pipe 145, the upper part of the O-ring 130 is still heated by the heater 120. Therefore, a cooling flange 160 which is coupled with the upper flange 140b is provided to prevent the upper part of the O-ring 130 from any thermal damage. A second water pipe 165 is provided within the cooling flange 160 and cooling water flows through the same.

A wire shaped metal seal 150 having an excellent thermal conductivity is inserted between the upper flange 140b and the cooling flange 160 to be pressed therebetween, in order to promote cooling of the upper part of the O-ring 130 more efficiently.

[Embodiment 2]

An apparatus for fabricating a semiconductor device according to the second embodiment of the present invention will now be described in reference to the FIG. 3.

Referring to FIG. 3, a reaction space sealed from the outer atmosphere is provided by a quartz tube 111, in which a bulk head 121 is provided at one end of the quartz tube 111 to close the inner space of the quartz tube from the outer atmosphere. The bulk head 121 has a outlet pipe 141 for exhausting gas from the inner space of the quartz tube 111.

Also, an O-ring 131 is inserted between the bulk head 121 and the quartz tube 111 to prevent any leak from taking place. In this case, the O-ring 131 is pressed onto the quartz tube 111 by the bulk head 121.

A heater (not shown) for supplying heat required for a fabrication process may be provided to surround the outer surface of the quartz tube 11, or alternatively provided to supporting means for settling a wafer within the quartz tube 11.

In order to protect the O-ring 131 from any thermal damage due to heat produced by the heater, a water pipe 161 adapted for cooling water to flow through the same is provided within the bulk head 121. Also, a wire shaped metal seal 151 having an excellent thermal conductivity is inserted between the bulk head 121 and the quartz tube 111, in order to promote cooling of the O-ring 131 more efficiently by the water pipe 161.

According to the foregoing embodiments of the present invention, efficiency of a cooling water can be maximized by use of a metal seal so that the O-ring close to a high temperature part can be protected from any thermal damage. Therefore, in a reaction chamber or a quartz tube, any leak of gas from a sealed part of the O-ring or any thermal deformation and adhering of the O-ring can be prevented.

Hereinabove the present invention has been described in reference to preferred embodiments, but various other modifications and variations will be apparent to those skilled in the art without departing from the scope and spirit of the present invention.

What is claimed is:

1. An apparatus for fabricating a semiconductor device comprising:
a reaction chamber having an upper chamber with an upper flange and a lower chamber with a lower flange, said upper and lower flanges being coupled to define a reaction space sealed from the outer atmosphere;
an O-ring inserted between said upper and lower flanges;
a heater arranged within said reaction chamber;
a water pipe provided within said lower flange;
a metal seal provided to the upper surface of said lower flange of said reaction chamber; and
a cooling flange provided with a water pipe adapted for cooling water to flow through said water pipe, said cooling flange being coupled with the upper flange of said reaction chamber so that said metal seal can be pressed onto the upper surface of said upper flange of said reaction chamber.

2. The apparatus of claim 1, wherein said metal seal has a wire shape.

3. An apparatus for fabricating a semiconductor device comprising:
a quartz tube for providing a reaction space sealed from the outer atmosphere;
a heater for heating the inside of said quartz tube;
a bulk head surrounding said quartz tube, and provided with a water pipe in the inside;
an O-ring inserted between said bulk head and said quartz tube and pressed onto said quartz tube by said bulk head; and
a metal seal inserted between said bulk head and said quartz tube close to said O-ring.

4. The apparatus of claim 3, wherein said metal seal has a wire shape.
